(19) United States
(12) Patent Application Publication
(10) Pub. No.: US 2018/0213635 A1
(43) Pub. Date: Jul. 26, 2018

(54) RESIN COMPOSITION AND MULTILAYER SUBSTRATE

(71) Applicant: SEKISUI CHEMICAL CO., LTD., Osaka-city, Osaka (JP)

(72) Inventors: Susumu Baba, Tsukuba-city (JP); Tatsushi Hayashi, Tsukuba-city (JP); Hiroshi Kouyanagi, Tsukuba-city (JP)

(21) Appl. No.: 15/747,714

(22) PCT Filed: Sep. 29, 2016
(86) PCT No.: PCT/JP2016/078800

§ 371 Date: Jan. 25, 2018

(30) Foreign Application Priority Data
Sep. 30, 2015 (JP) 2015-195421

(51) Int. Cl. H05K 1/02; C08K 3/013; C08K 3/36; C08G 59/40; H05K 1/03

(52) U.S. Cl. CPC H05K 1/024; C08K 3/013; C08K 3/36; C08G 59/4007; H01B 3/40; H05K 1/0271; H05K 2201/0129; H05K 2201/0209; H05K 1/0373

(57) ABSTRACT

Provided is a resin composition which is capable of improving the bending property and the cutting processability of a B-stage film and which is capable of reducing the dielectric loss tangent of a cured product and improving the thermal dimensional stability of the cured product. The resin composition according to the present invention includes an epoxy compound, a curing agent and an inorganic filler, the epoxy compound containing a liquid epoxy compound having a viscosity of 500 mPa·s or less at 25° C., in an amount of 1% by weight or more and 10% by weight or less based on 100% by weight of the whole of the epoxy compound.

### TECHNICAL FIELD

The present invention relates to a resin composition including an epoxy compound, a curing agent and an inorganic filler. The present invention also relates to a multilayer substrate obtained by using the resin composition.

### BACKGROUND ART

Various resin compositions have been used heretofore for obtaining electronic components such as laminated plates and printed wiring boards. For example, in a multilayer printed wiring board, a resin composition is used for forming an insulating layer for insulation between inner layers or forming an insulating layer positioned at a surface layer portion. On the surface of the insulating layer, a wiring which is generally a metal is laminated. In addition, for forming an insulating layer, a B-stage film obtained by forming the resin composition into a film may be used. The resin composition and the B-stage film are used as insulating materials for a printed wiring board including a build-up film.

As one example of the resin composition, a curable epoxy composition containing an epoxy compound, an active ester compound and a filler is disclosed in Patent Document 1 below. In this curable epoxy composition, the content of an epoxy compound having a softening point of 100° C. or lower is 80% by weight or more based on 100% by weight of the whole of the epoxy compound.

### RELATED ART DOCUMENT

### Patent Document

Patent Document 1: JP 2015-143302 A

### SUMMARY OF THE INVENTION

### Problems to be Solved by the Invention

For reducing a transmission loss, the insulating layer is required to have a reduced dielectric loss tangent. In addition, for reducing occurrence of peeling and warpage, the insulating layer is required to have high thermal dimensional stability such that the dimension is hardly changed by heat.

However, when a conventional resin composition as described in Patent Document 1 is formed into a film to obtain a B-stage film, the B-stage film may be cracked when bent, and chips (chippings) may be generated when the B-stage film is cut into a predetermined size.

An object of the present invention is to provide a resin composition which is capable of improving the bending property and the cutting processability of a B-stage film and which is capable of reducing the dielectric loss tangent of a cured product and improving the thermal dimensional stability of the cured product.

### Means for Solving the Problems

According to a broad aspect of the present invention, there is provided a resin composition including an epoxy compound, a curing agent and an inorganic filler, the epoxy compound containing a liquid epoxy compound having a viscosity of 500 mPa·s or less at 25° C., in an amount of 1% by weight or more and 10% by weight or less based on 100% by weight of the whole of the epoxy compound.

In a specific aspect of the resin composition according to the present invention, the content of the inorganic filler is 60% by weight or more based on 100% by weight of components excluding a solvent in the resin composition.

In a specific aspect of the resin composition according to the present invention, the inorganic filler contains silica.

In a specific aspect of the resin composition according to the present invention, the curing agent contains an active ester compound.

In a specific aspect of the resin composition according to the present invention, the liquid epoxy compound has a viscosity of 10 mPa·s or more at 25° C.

In a specific aspect of the resin composition according to the present invention, the liquid epoxy compound has a cycloaliphatic structure, a glycidylamine structure having an aromatic ring structure, or a resorcinol structure.

In a specific aspect of the resin composition according to the present invention, the liquid epoxy compound is a liquid epoxy compound which does not contain a silicon atom.

In a specific aspect of the resin composition according to the present invention, the resin composition includes a thermoplastic resin.

According to a broad aspect of the present invention, there is provided a multilayer substrate including a circuit board, and an insulating layer disposed on the circuit board, the insulating layer being a cured product of the resin composition.

### Effect of the Invention

A resin composition according to the present invention includes an epoxy compound, a curing agent and an inorganic filler, the epoxy compound containing a liquid epoxy compound having a viscosity of 500 mPa·s or less at 25° C., in an amount of 1% by weight or more and 10% by weight or less based on 100% by weight of the whole of the epoxy compound. Thus, the bending property and the cutting processability of a B-stage film can be improved, the dielectric loss tangent of a cured product can be reduced, and the thermal dimensional stability of the cured product can be improved.

### BRIEF DESCRIPTION OF DRAWINGS

FIG. 1 is a sectional view schematically showing a multilayer substrate obtained by using a resin composition according to one embodiment of the present invention.

### MODE FOR CARRYING OUT THE INVENTION

Hereinafter, the present invention will be described in detail.

A resin composition according to the present invention includes an epoxy compound, a curing agent and an inorganic filler. In the resin composition according to the present invention, the epoxy compound contains a liquid epoxy compound having a viscosity at 25° C. of 500 mPa·s or less. In the resin composition according to the present invention, the content of a liquid epoxy compound having a viscosity of 500 mPa·s or less at 25° C. is 1% by weight or more and 10% by weight or less based on 100% by weight of the whole of the epoxy compound.

In the present invention, since the resin composition has the configuration described above, the bending property and the cutting processability of a B-stage film can be improved, the dielectric loss tangent of a cured product can be reduced, and the thermal dimensional stability of the cured product can be improved. It is possible to ensure that the B-stage film is hardly cracked when bent. Occurrence of chips (chippings) can be suppressed when the B-stage film is cut into a predetermined size. When the composition including ingredients in the present invention has a configuration in which the content of the liquid epoxy compound having a viscosity of 500 mPa·s or less at 25° C. is 1% by weight or more and 10% by weight or less based on 100% by weight of the whole of the epoxy compound, an increase in dielectric loss tangent can be suppressed, and deterioration of thermal dimensional stability can be suppressed as compared to a case where the composition does not have such a configuration.

In the present invention, the content of the inorganic filler can be increased, and a low dielectric loss tangent and high dimensional stability can be achieved at a further high level.

On the other hand, when in a conventional resin composition, the content of the inorganic filler is increased, or the polarity of a resin component is decreased in order to achieve a low dielectric loss tangent, the bending property and the cutting processability of the B-stage film tend to be deteriorated. On the other hand, in the present invention, a low dielectric loss tangent can be achieved, and the bending property and the cutting processability of the B-stage film can be improved.

In addition, in a conventional resin composition, when the content of the inorganic filler is increased, or the rigidity of a resin component is enhanced in order to achieve high thermal dimensional stability, the bending property and the cutting processability of the B-stage film tend to be deteriorated. On the other hand, in the present invention, high thermal dimensional stability can be achieved, and the bending property and the cutting processability of the B-stage film can be improved.

The resin composition is heated at 190° C. for 90 minutes to obtain a cured product. The average linear expansion coefficient of the cured product at 25° C. or higher and 150° C. or lower is preferably 30 ppm/° C. or less, more preferably 25 ppm/° C. or less. When the average linear expansion coefficient is the above-mentioned upper limit or less, further excellent thermal dimensional stability is obtained. The dielectric loss tangent of the cured product at a frequency of 1.0 GHz is preferably 0.005 or less, more preferably 0.0045 or less. When the dielectric loss tangent is the upper limit or less, the transmission loss is further suppressed.

A multilayer substrate according to the present invention includes a circuit board, and an insulating layer disposed on the circuit board. The insulating layer is the cured product of the resin composition.

Hereinafter, details of components to be used in the resin composition according to the present invention, uses of the resin composition according to the present invention, and the like will be described.

[Epoxy Compound]

The epoxy compound contained in the resin composition is not particularly limited. As the epoxy compound, a previously known epoxy compound can be used. The epoxy compound refers to an organic compound having at least one epoxy group. As the epoxy compound, only one kind of epoxy compound may be used, or two or more kinds of epoxy compounds may be used in combination.

Examples of the epoxy compound include bisphenol A-type epoxy resins, bisphenol F-type epoxy resins, bisphenol S-type epoxy resins, phenol novolak-type epoxy resins, biphenyl-type epoxy resins, biphenyl novolak-type epoxy resins, biphenol-type epoxy resins, naphthalene-type epoxy resins, fluorene-type epoxy resins, phenol aralkyl-type epoxy resins, naphthol aralkyl-type epoxy resins, dicyclopentadiene-type epoxy resins, anthracene-type epoxy resins, epoxy resins having an adamantane skeleton, epoxy resins having a tricyclodecane skeleton, and epoxy resins having a triazine nucleus in a skeleton.

In the present invention, the epoxy compound contains a liquid epoxy compound in an amount of 1% by weight or more and 10% by weight or less based on 100% by weight of the whole of the epoxy compound, the liquid epoxy compound having a viscosity of 500 mPa·s or less at 25° C.

Examples of the liquid epoxy compound include monomer-type epoxy compounds. For further improving the thermal dimensional stability and the dielectric loss tangent of the resin cured product, the liquid epoxy compound is preferably a dicyclopentadiene-type epoxy compound or an epoxy compound having a benzene ring, more preferably a dicyclopentadiene-type epoxy monomer or an epoxy monomer having a benzene ring. For further improving the thermal dimensional change property of the cured product, the liquid epoxy compound is more preferably a liquid epoxy compound having two or more epoxy groups.

The liquid epoxy compound is preferably a liquid epoxy compound which does not contain a silicon atom. By use of this liquid epoxy compound, bending property and cutting processability are more easily improved.

Examples of the liquid epoxy compound include 2-ethylhexyl glycidyl ether, hexanediol diglycidyl ether, butanediol diglycidyl ether, cyclohexane dimethanol diglycidyl ether, dicyclopentadiene dimethanol diglycidyl ether, resorcinol diglycidyl ether and diglycidyl aniline.

For further reducing the dimensional change of the cured product by heat, it is more preferable that the liquid epoxy compound has a cyclic structure. Examples of the cyclic structure include cycloaliphatic structures and aromatic ring structures. The cycloaliphatic structure is preferably a cyclohexane structure or a dicyclopentadiene structure. Examples of the aromatic ring structure include benzene ring structures and naphthalene ring structures. Examples of the structure having a benzene ring structure include glycidylamine structures having an aromatic ring structure, and resorcinol structures. For further effectively exhibiting the effect of the present invention, the liquid epoxy compound has preferably a cycloaliphatic structure, a glycidylamine structure having an aromatic ring structure, or a resorcinol structure, more preferably a resorcinol structure.

For further improving the bending property and the cutting processability of the B-stage film, it is preferable that the epoxy compound contains an epoxy compound which is solid at 25° C. together with the liquid epoxy resin.

For further improving the bending property and the cutting processability of the B-stage film, the viscosity of the liquid epoxy compound at 25° C. is preferably 400 mPa·s or less. For preventing volatilization of the resin during thermal curing, the viscosity of the liquid epoxy compound at 25° C. is preferably 10 mPa·s or more, and more preferably 30 mPa·s or more. For further improving the bending property and the cutting processability of the B-stage film, it is preferable that the liquid epoxy compound includes a liquid epoxy compound having a viscosity of 400 mPa·s or less at 25° C. as the liquid epoxy compound having a viscosity of 500 mPa·s or less at 25° C. For preventing volatilization of the resin during thermal curing, it is preferable that the liquid epoxy compound includes a liquid epoxy compound having a viscosity of 10 mPa·s or more at 25° C., more preferably a liquid epoxy compound having a viscosity of 30 mPa·s or more at 25° C., as the liquid epoxy compound having a viscosity of 500 mPa·s or less at 25° C.

For further improving the thermal dimensional stability and the dielectric loss tangent of the resin cured product, the content of the liquid epoxy compound having a viscosity of 500 mPa·s or less at 25° C. is preferably 9% by weight or less based on 100% by weight of the whole of the epoxy compound.

For further improving the bending property and the cutting processability of the B-stage film, the content of the liquid epoxy compound having a viscosity of 400 mPa·s or less at 25° C. is preferably 9% by weight or less based on 100% by weight of the whole of the epoxy compound.

For further improving the thermal dimensional stability and the dielectric loss tangent of the resin cured product, the content of the liquid epoxy compound having a viscosity of 10 mPa·s or more and 500 mPa·s or less at 25° C. is preferably 1% by weight or more, and preferably 10% by weight or less, more preferably 9% by weight or less based on 100% by weight of the whole of the epoxy compound. For further improving the thermal dimensional stability and the dielectric loss tangent of the resin cured product, the content of the liquid epoxy compound having a viscosity of 30 mPa·s or more and 500 mPa·s or less at 25° C. is preferably 1% by weight or more, and preferably 10% by weight or less, more preferably 9% by weight or less based on 100% by weight of the whole of the epoxy compound. For further improving the thermal dimensional stability and the dielectric loss tangent of the resin cured product, the content of the liquid epoxy compound having a viscosity of 10 mPa·s or more and 400 mPa·s or less at 25° C. is preferably 1% by weight or more, and preferably 10% by weight or less, more preferably 9% by weight or less based on 100% by weight of the whole of the epoxy compound. For further improving the thermal dimensional stability and the dielectric loss tangent of the resin cured product, the content of the liquid epoxy compound having a viscosity of 30 mPa·s or more and 400 mPa·s or less at 25° C. is preferably 1% by weight or more, and preferably 10% by weight or less, more preferably 9% by weight or less based on 100% by weight of the whole of the epoxy compound.

[Curing Agent]

The curing agent contained in the resin composition is not particularly limited. As the curing agent, a previously known curing agent can be used. As the curing agent, only one kind of curing agent may be used, or two or more kinds of curing agents may be used in combination.

Examples of the curing agent include cyanate ester compounds (cyanate ester curing agents), phenol compounds (phenol curing agents), amine compounds (amine curing agents), thiol compounds (thiol curing agents), imidazole compounds, phosphine compounds, acid anhydrides, active ester compounds and dicyandiamides. Preferably, the curing agent has a functional group capable of reacting with an epoxy group of the epoxy compound.

Examples of the cyanate ester compound include a novolak-type cyanate ester resins, bisphenol-type cyanate ester resins, and prepolymers obtained by partially trimerizing these resins. Examples of the novolak-type cyanate ester resin include phenol novolak-type cyanate ester resins and alkylphenol-type cyanate ester resins. Examples of the bisphenol-type cyanate ester resin include bisphenol A-type cyanate ester resins, bisphenol E-type cyanate ester resins and tetramethyl bisphenol F-type cyanate ester resins.

Examples of the commercially available product of the cyanate ester compound include phenol novolak-type cyanate ester resins (“PT-30” and “PT-60” manufactured by Lonza Japan Co., Ltd.) and prepolymers obtained by trimerizing a bisphenol type cyanate ester resin (“BA-230S”, “BA-3000S”, “BTP-1000S” and “BTP-6020S” manufactured by Lonza Japan Co., Ltd.).

Examples of the phenol compound include novolac-type phenol, biphenol-type phenol, naphthalene-type phenol, dicyclopentadiene-type phenol, aralkyl-type phenol and dicyclopentadiene-type phenol.

Examples of the commercially available product of the phenol compound include novolac-type phenol (“TD-2091” manufactured by DIC Corporation), biphenyl novolak-type phenol (“MEH-7851” manufactured by MEIWA PLASTIC INDUSTRIES, LTD.), aralkyl-type phenol compounds (“MEH-7800” manufactured by MEIWA PLASTIC INDUSTRIES, LTD.), and phenol having an aminotriazine skeleton (“LA 1356” and “LA 3018-50P” manufactured by DIC Corporation).

For improving bending property while suppressing an increase in dielectric loss tangent, and improving cutting processability, it is preferable that the curing agent contains an active ester compound. The active ester compound refers to a compound containing at least one ester bond in the structure, and having an aromatic ring bonded to both sides of the ester bond. The active ester compound is obtained by, for example, a condensation reaction of a carboxylic acid compound or a thiocarboxylic acid compound with a hydroxy compound or a thiol compound. Examples of the active ester compound include compounds represented by the following formula (1).

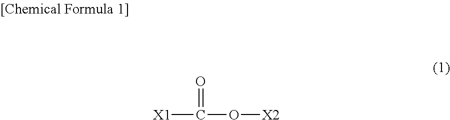

In the formula (1), X1 and X2 each represent a group containing an aromatic ring. Preferred examples of the group containing an aromatic ring include benzene rings optionally having a substituent, and naphthalene rings optionally having a substituent. Examples of the substituent include hydrocarbon groups. The number of carbon atoms number in the hydrocarbon group is preferably or less, more preferably 6 or less, still more preferably 4 or less.

Examples of the combination of X1 and X2 include combinations of a benzene ring optionally having a substituent and a benzene ring optionally having a substituent, combinations of a benzene ring optionally having a substituent and a naphthalene ring optionally having a substituent, and combinations of a naphthalene ring optionally having a substituent and a naphthalene ring optionally having a substituent.

The active ester compound is not particularly limited. For decreasing the dielectric loss tangent of the cured product and improving the thermal dimensional stability of the cured product, it is more preferable that the main chain skeleton of the active ester contains a naphthalene ring. Examples of the commercially available product of the active ester compound include “HPC-8000-65T”, “EXB9416-70BK” and “EXB8100-65T” manufactured by DIC Corporation.

The content of the curing agent is preferably 25 parts by weight or more, more preferably 50 parts by weight or more, and preferably 200 parts by weight or less, more preferably 150 parts by weight or less based on 100 parts by weight of the epoxy compound. When the content of the curing agent is the above-mentioned lower limit or more and the above-mentioned upper limit or less, further excellent curability is obtained, and a dimensional change of the cured product by heat and volatilization of a remaining unreacted component can be further suppressed.

The total content of the epoxy compound and the curing agent based on 100% by weight of components other than the inorganic filler and solvent in the resin composition is preferably 75% by weight or more, more preferably 80% by weight or more, and preferably 99% by weight or less, more preferably 97% by weight or less. When the total content of the epoxy compound and the curing agent is the above-mentioned lower limit or more and the above-mentioned upper limit or less, a further favorable cured product is obtained, and a dimensional change of the cured product by heat can be further suppressed.

[Thermoplastic Resin]

Examples of the thermoplastic resin include polyvinyl acetal resins and phenoxy resins. As the thermoplastic resin, only one kind of thermoplastic resin, or two or more kinds of thermoplastic resins may be used in combination.

For effectively reducing the dielectric loss tangent and effectively improving the adhesion of the metal wiring regardless of the curing environment, the thermoplastic resin is preferably a phenoxy resin. The use of the phenoxy resin suppresses deterioration of embedability of a resin film in holes and irregularities of a circuit board, and unevenness of the inorganic filler. In addition, the use of the phenoxy resin makes it possible to adjust the melt viscosity, so that the dispersibility of the inorganic filler is improved, and the resin composition or the B-stage film is hardly wetted and spread in an unintended region in a curing process. The phenoxy resin contained in the resin composition is not particularly limited. As the phenoxy resin, a previously known phenoxy resin can be used. As the phenoxy resin, only one kind of phenoxy resin, or two or more kinds of phenoxy resins may be used in combination.

Examples of the phenoxy resin include phenoxy resins having a skeleton such as a bisphenol A-type skeleton, a bisphenol F type skeleton, a bisphenol S-type skeleton, a biphenyl skeleton, a novolac skeleton, a naphthalene skeleton or an imide skeleton.

Examples of the commercially available product of the phenoxy resin include “YP 50”, “YP 55” and “YP 70” manufactured by NIPPON STEEL & SUMIKIN CHEMICAL CO., LTD., and “1256B 40”, “4250”, “4256H 40”, “4275”, “YX 6954 BH 30” and “YX 8100 BH 30” manufactured by Mitsubishi Chemical Corporation.

For obtaining a resin film having further excellent storage stability, the weight average molecular weight of the thermoplastic resin is preferably 5000 or more, more preferably 10000 or more, and preferably 100000 or less, more preferably 50000 or less.

The weight average molecular weight of the thermoplastic resin refers to a weight average molecular weight in terms of polystyrene as measured by gel permeation chromatography (GPC).

The content of the thermoplastic resin is not particularly limited. The content of the thermoplastic resin (the content of a phenoxy resin when the thermoplastic resin is the phenoxy resin) based on 100% by weight of components other than the inorganic filler and solvent in the resin composition is preferably 2% by weight or more, more preferably 4% by weight or more, and preferably 15% by weight or less, more preferably 10% by weight or less. When the content of the thermoplastic resin is the above-mentioned lower limit or more and the above-mentioned upper limit or less, embedability of the resin composition or the B-stage film in holes or irregularities of the circuit board is improved. When the content of the thermoplastic resin is the above-mentioned lower limit or more, formation of the resin composition into a film is further facilitated, and a more favorable insulating layer is obtained. When the content of the thermoplastic resin is the above-mentioned upper limit or less, the thermal expansion coefficient of the cured product is further reduced. The surface roughness of the surface of the cured product is further reduced, and the adhesive strength between the cured product and the metal layer is further increased.

[Inorganic Filler]

The resin composition contains an inorganic filler. The use of the inorganic filler further reduces a dimensional change of the cured product by heat. In addition, the dielectric loss tangent of the cured product is further reduced.

Examples of the inorganic filler include silica, talc, clay, mica, hydrotalcite, alumina, magnesium oxide, aluminum hydroxide, aluminum nitride and boron nitride.

For reducing the surface roughness of the surface of the cured product to further increase the adhesive strength between the cured product and the metal layer, forming a further fine wiring on the surface of the cured product, and imparting more favorable insulation reliability to the cured product, the inorganic filler is preferably silica or alumina, more preferably silica, still more preferably fused silica. The use of silica further reduces the thermal expansion coefficient of the cured product, and effectively decreases the surface roughness of the surface of the cured product to effectively increase the adhesive strength between the cured product and the metal layer. Preferably, the silica has a spherical shape.

The mean particle diameter of the inorganic filler is preferably 10 nm or more, more preferably 50 nm or more, still more preferably 150 nm or more, and preferably 20 μm or less, more preferably 10 μm or less, still more preferably 5 μm or less, especially preferably 1 μm or less. When the mean particle diameter of the inorganic filler is the above-mentioned lower limit or more and the above-mentioned upper limit or less, pores formed by a roughening treatment or the like have a very small size, so that the number of pores increases. As a result, the adhesive strength between the cured product and the metal layer is further increased.

As the mean particle diameter of the inorganic filler, a value of a median diameter (d50) corresponding to a particle diameter at which the amount of particles having larger particle diameters and the amount of particles having smaller particles each occupy 50% of the total amount of particles is employed. The mean particle diameter can be measured using a particle diameter distribution measuring apparatus of laser diffraction/scattering type.

The particles of the inorganic filler are each preferably spherical, more preferably spherical silica. Here, the surface roughness of the surface of the cured product is effectively reduced, and the adhesive strength between the insulating layer and the metal layer is effectively increased. When the particles of the inorganic filler are each spherical, the aspect ratio of each of the particles of the inorganic filler is preferably 2 or less, more preferably 1.5 or less.

The inorganic filler is preferably surface-treated, more preferably surface-treated with a coupling agent, still more preferably surface-treated with a silane coupling agent. Accordingly, the surface roughness of the surface of the roughened cured product is further reduced to further increase the adhesion strength between the cured product and the metal layer, a further fine wiring is formed on the surface of the cured product, and further favorable inter-wiring insulation reliability and interlayer insulation reliability can be imparted to the cured product.

Examples of the coupling agent include silane coupling agents, titanium coupling agents and aluminum coupling agents. Examples of the silane coupling agent include methacrylic silane, acrylic silane, aminosilane, imidazolesilane, vinylsilane and epoxysilane.

The content of the inorganic filler based on 100% by weight of components other than the solvent in the resin composition is preferably 25% by weight or more, more preferably 30% by weight or more, still more preferably 40% by weight or more, especially preferably 50% by weight or more, most preferably 60% by weight or more, and preferably 99% by weight or less, more preferably 85% by weight or less, still more preferably 80% by weight or less, especially preferably 75% by weight or less. When the total content of the inorganic filler is the above-mentioned lower limit or more and the above-mentioned upper limit or less, the adhesive strength between the cured product and the metal layer is further increased, a further fine wiring is formed on the surface of the cured product, and when the amount of the inorganic filler is in the above-mentioned range, it is also possible to reduce a dimensional change of the cured product by heat.

[Curing Accelerator]

Preferably, the resin composition contains a curing accelerator. The use of the curing accelerator further increases the curing rate. By quickly curing the resin film, the number of unreacted functional groups decreases, resulting in an increase in crosslinking density. The curing accelerator is not particularly limited, and a previously known curing accelerator can be used. As the curing accelerator, only one kind of curing accelerator may be used, or two or more kinds of curing accelerators may be used in combination.

Examples of the curing accelerator include imidazole compounds, phosphorus compounds, amine compounds and organometallic compounds.

Examples of the imidazole compound include 2-undecylimidazole, 2-heptadecylimidazole, 2-methylimidazole, 2-ethyl-4-methylimidazole, 2-phenylimidazole, 2-phenyl-4-methylimidazole, 1-benzyl-2-methylimidazole, 1-benzyl-2-phenylimidazole, 1,2-dimethylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-cyanoethyl-2-undecylimidazolium trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adducts, 2-phenylimidazole isocyanuric acid adducts, 2-methylimidazole isocyanuric acid adducts, 2-phenyl-4,5-dihydroxymethylimidazole and 2-phenyl-4-methyl-5-dihydroxymethylimidazole.

Examples of the phosphorus compound include triphenylphosphine.

Examples of the amine compound include diethylamine, triethylamine, diethylenetetramine, triethylenetetramine and 4,4-dimethylaminopyridine.

Examples of the organometallic compound include zinc naphthenate, cobalt naphthenate, tin octylate, cobalt octylate, bis-acetylacetonate cobalt (II) and tris-acetylacetonate cobalt (III).

The content of the curing accelerator is not particularly limited. The content of the curing accelerator based on 100% by weight of components other than the inorganic filler and solvent in the resin composition is preferably 0.01% by weight or more, more preferably 0.9% by weight or more, and preferably 5.0% by weight or less, more preferably 3.0% by weight or less. When the content of the curing accelerator is the above-mentioned lower limit or more and the above-mentioned upper limit or less, the resin film is efficiently cured. When the content of the curing accelerator is in a more preferred range, the storage stability of the resin composition is further improved, and a further favorable cured product can be obtained.

[Solvent]

The resin composition does not contain, or contains a solvent. By use of the solvent, the viscosity of the resin composition can be controlled to fall within a suitable range, and the coatability of the resin composition can be improved. In addition, the solvent may be used for obtaining a slurry containing the inorganic filler. As the solvent, only one kind of solvent may be used, or two or more kinds of solvents may be used in combination.

Examples of the solvent include acetone, methanol, ethanol, butanol, 2-propanol, 2-methoxyethanol, 2-ethoxyethanol, 1-methoxy-2-propanol, 2-acetoxy-1-methoxypropane, toluene, xylene, methyl ethyl ketone, N, N-dimethylformamide, methyl isobutyl ketone, N-methyl-pyrrolidone, n-hexane, cyclohexane, cyclohexanone, and naphtha which is a mixture.

Preferably, most of the solvent is removed when the resin composition is formed into a film. Accordingly, the boiling point of the solvent is preferably 200° C. or lower, more preferably 180° C. or lower. The content of the solvent in the resin composition is not particularly limited. The content of the solvent can be appropriately changed in consideration of the coatability of the resin composition, and so on.

[Other Components]

For the purpose of improving impact resistance, heat resistance, resin compatibility, workability, and the like, a leveling agent, a flame retardant, a coupling agent, a coloring agent, an antioxidant, an ultraviolet degradation inhibitor, an antifoaming agent, a thickener, a thixotropy imparting agent, a thermosetting resin other than the epoxy compound, and the like may be added.

Examples of the coupling agent include silane coupling agents, titanium coupling agents and aluminum coupling agents. Examples of the silane coupling agent include vinylsilane, aminosilane, imidazolesilane and epoxysilane.

Examples of the other thermosetting resin include polyphenylene ether resins, divinylbenzyl ether resins, polyarylate resins, diallyl phthalate resins, polyimide resins, benzoxazine resins, benzoxazole resins, bismaleimide resins and acrylate resins.

(Resin Film (B-Stage Film) and Laminated Film)

A resin film (B-stage film) is obtained by molding the resin composition into a film shape. The resin film is preferably a B-stage film.

For further uniformly controlling the curing degree of the resin film, the thickness of the resin film is preferably 5 μm or more, and preferably 200 μm or less.

Examples of the method for forming the resin composition into a film shape include an extrusion molding method in which a resin composition is melted and kneaded using an extruder, extruded, and then molded into a film shape by a T-die, a circular die or the like, a casting molding method in which a resin composition containing a solvent is cast and molded into a film shape, and other previously known film molding methods. An extrusion molding method or a casting molding method is preferable because the method is capable of producing a thin film. Films include sheets.

A resin film which is a B-stage film can be obtained by molding the resin composition into a film shape, and drying by heating the film, for example, at 50 to 150° C. for 1 to 10 minutes to such an extent that curing by heat does not excessively proceed.

A film-shaped resin composition that can be obtained by a drying step as described above is referred to as a B-stage film. The B-stage film is a film-shaped resin composition in a semi-cured state. The semi-cured product is not completely cured, and curing thereof may further proceed.

The resin film is not required to be a prepreg. When the resin film is not a prepreg, migration does not occur along a glass cloth or the like. In addition, irregularities caused by a glass cloth are not generated on the surface in lamination or pre-curing of the resin film. The resin composition can be suitably used for forming a laminated film including a metal foil or a base material, and a resin film laminated on a surface of the metal foil or the base material. The resin film in the laminated film is formed from the resin composition. The metal foil is preferably a copper foil.

Examples of the base material of the laminated film include polyester resin films such as polyethylene terephthalate films and polybutylene terephthalate films, olefin resin films such as polyethylene films and polypropylene films, and polyimide resin films. The surface of the base material may be subjected to a release treatment as necessary.

When the resin composition and the resin film are used as an insulating layer of a circuit, the thickness of the insulating layer formed from the resin composition or the resin film is preferably the thickness of a conductor layer (metal layer) or more that forms the circuit. The thickness of the insulating layer is preferably 5 μm or more, and preferably 200 μm or less.

(Printed Wiring Board) The resin composition and the resin film are suitably used for forming an insulating layer in a printed wiring board.

The printed wiring board is obtained by, for example, subjecting the resin film to hot press-molding.

A metal foil can be laminated to one surface or both surfaces of the resin film. The method for laminating the resin film and the metal foil is not particularly limited, and a known method can be used. The resin film can be laminated to the metal foil by, for example, performing heating or applying a pressure without heating with use of an apparatus such as a parallel flat plate press machine or a roll laminator.

(Copper-Clad Laminated Plate and Multilayer Substrate)

The resin composition and the resin film are suitably used for obtaining a copper-clad laminated plate. One example of the copper-clad laminated plate is a copper-clad laminated plate including a copper foil, and a resin film laminated to one surface of the copper foil. The resin film of the copper-clad laminated plate is formed from the resin composition.

The thickness of the copper foil of the copper-clad laminated plate is not particularly limited. The thickness of the copper foil is preferably within a range of 1 to 50 μm. For increasing the adhesive strength between the insulating layer obtained by curing the resin film and the copper foil, it is preferable that the copper foil has fine irregularities on a surface thereof. The method of forming the irregularities is not particularly limited. Examples of the method for forming the irregularities include a method for forming irregularities by a treatment using a known chemical solution.

The resin composition and the resin film are suitably used for obtaining a multilayer substrate. One example of the multilayer substrate is a multilayer substrate including a circuit board, and an insulating layer laminated on a surface of the circuit board. The insulating layer of the multilayer substrate is formed from the resin film using a resin film obtained by molding the resin composition into a film shape. In addition, using a laminated film, the insulating layer of the multilayer substrate may be formed from the resin film of the laminated film. Preferably, the insulating layer is laminated on a surface of the circuit board which is provided with circuits. Preferably, a part of the insulating layer is embedded between the circuits.

In the multilayer substrate, it is preferable that a surface of the insulating layer on a side opposite to the surface on which the circuit board is laminated is subjected to a roughening treatment.

As a roughening treatment method, an appropriate roughening treatment method can be used. The surface of the insulating layer may be subjected to a swelling treatment before the roughening treatment.

In addition, it is preferable that the multilayer substrate further includes a copper-plated layer laminated on the roughening-treated surface of the insulating layer.

Another example of the multilayer substrate is a multilayer substrate including a circuit board, an insulating layer laminated on a surface of the circuit board, and a copper foil laminated on a surface of the insulating layer on a side opposite to the surface on which the circuit board is laminated. Preferably, the insulating layer and the copper foil are formed by providing a copper-clad laminated plate including a copper foil and a resin film laminated on one surface of the copper foil, and curing the resin film. In addition, it is preferable that the copper foil is subjected to an etching treatment, and forms a copper circuit.

Another example of the multilayer substrate is a multilayer substrate including a circuit board, and a plurality of insulating layers laminated on a surface of the circuit board. At least one of the plurality of insulating layers disposed on the circuit board is formed using a resin film obtained by molding the resin composition into a film shape. Preferably, the multilayer substrate further includes a circuit laminated on at least one surface of the insulating layer formed using the resin film.

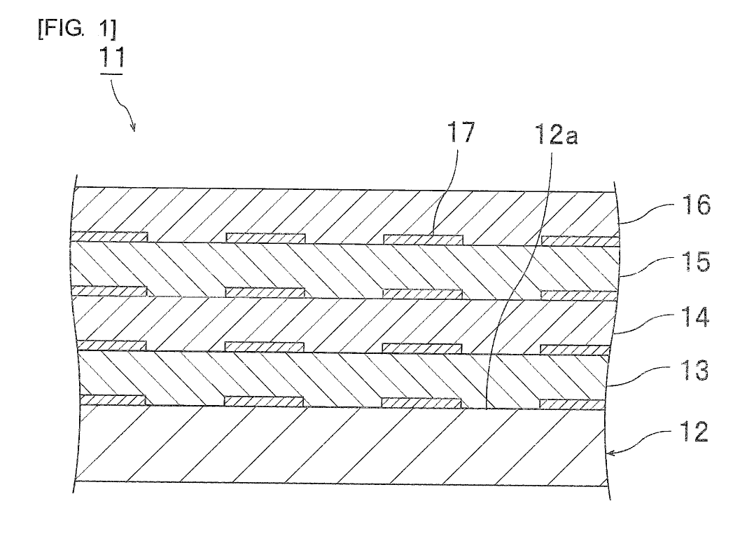

FIG. 1 is a sectional view schematically showing a multilayer substrate obtained by using a resin composition according to one embodiment of the present invention.

In a multilayer substrate 11 shown in FIG. 1, a plurality of insulating layers 13 to 16 are laminated on an upper surface 12a of a circuit board 12. The insulating layers 13 to 16 are cured material layers. A metal layer 17 is formed in a region constituting a part of the upper surface 12a of the circuit board 12. On the insulating layers 13 to 15 which are layers other than the insulating layer 16 situated on an outer surface opposite to the circuit board 12, among a plurality of insulating layers 13 to 16, the metal layer 17 is formed in a region constituting a part of the upper surface. The metal layer 17 forms a circuit. The metal layer 17 is disposed between the circuit board 12 and the insulating layer 13, and between adjacent layers among the laminated insulating layers 13 to 16. The lower metal layer 17 and the upper metal layer 17 are connected to each other by at least one of via-hole connection and through-hole connection (not illustrated).

In the multilayer substrate 11, the insulating layers 13 to 16 are formed from the resin composition. In this embodiment, surfaces of the insulating layers 13 to 16 are subjected to a roughening treatment, and therefore fine pores (not illustrated) are formed on the surfaces of the insulating layers 13 to 16. In addition, the metal layer extends into the fine pores. In addition, in the multilayer substrate 11, the width-direction size (L) of the metal layer 17 and the width-direction dimension (S) of a portion which is not provided the metal layer 17 can be reduced. In addition, in the multilayer substrate 11, favorable insulation reliability is imparted between the upper metal layer and the lower metal layer which are not connected by via-hole connection and through-hole connection (not illustrated). In preparation of the insulating layer, a roughening treatment may be performed, a swelling treatment may be performed, or a desmear treatment may be performed. Preferably, the resin composition is used for obtaining a cured product to be subjected to a roughening treatment or a desmear treatment.

Hereinafter, the present invention will be described in detail by way of examples and comparative examples. The present invention is not limited to the following examples.

The following components were used. Using a viscometer (“TVE-33H” manufactured by TOKI SANGYO CO., LTD), the viscosity of the epoxy compound was measured at 25° C., and at 5 rpm with 1° 34′×R24 used as a cone rotor.

(Epoxy Compound)

Biphenyl-type epoxy resin (“NC 3000” manufactured by Nippon Kayaku Co., Ltd.; solid at 25° C.)

Dicyclopentadiene-type epoxy resin (“XD 1000” manufactured by Nippon Kayaku Co., Ltd.; solid at 25° C.)

Dicyclopentadiene dimethanol diglycidyl ether (dicyclopentadiene-type epoxy resin; “EP-4088S” manufactured by ADEKA CORPORATION; viscosity: 230 mPa·s at 25° C.)

Diglycidylaniline (glycidylamine-type epoxy resin; “GAN” manufactured by Nippon Kayaku Co., Ltd.; viscosity: 130 mPa·s at 25° C.)

Diglycidylaniline (glycidylamine-type epoxy resin; “EP-3980S” manufactured by ADEKA CORPORATION; viscosity: 30 mPa·s at 25° C.)

Cyclohexane dimethanol diglycidyl ether (“EX-216L” manufactured by Nagase ChemteX Corporation; viscosity: 55 mPa·s at 25° C.)

Resorcinol diglycidyl ether (“EX-201-IM” manufactured by Nagase ChemteX Corporation; viscosity: 400 mPa·s at 25° C.)

Bisphenol A-type epoxy resin (“840-S” manufactured by DIC Corporation; viscosity: 10000 mPa·s at 25° C.)

Bisphenol-F type epoxy resin (“830-S” manufactured by DIC Corporation; viscosity: 4000 mPa·s at 25° C.)

(Curing Agent) Active ester resin-containing liquid (“EXB-9416-70 BK” manufactured by DIC Corporation, solid content: 70% by weight)

(Curing Accelerator)

Imidazole compound (“2P4 MZ” manufactured by SHIKOKU CHEMICALS CORPORATION)

(Thermoplastic Resin)

Phenoxy resin-containing liquid (“YX 6954 BH 30” manufactured by Mitsubishi Chemical Corporation; solid content: 30% by weight)

(Inorganic Filler)

“C4 silica” manufactured by Admatechs; solid content: 75% by weight)

### Examples 1 to 7 and Comparative Examples 1 to 6

The components shown in Tables 1 and 2 below were blended in a blending amount as shown in Tables 1 and 2 below, and were stirred at 1200 rpm for 1 hour by a stirrer to obtain a resin composition.

Using an applicator, the obtained resin composition (varnish) was applied onto a release treatment surface of a polyethylene terephthalate (PET) film (“XG 284” manufactured by Toray Industries, Inc.; thickness: 25 μm), and then dried in a gear oven at 100° C. for 2.5 minutes to volatilize a solvent. In this way, a laminated film including a PET film, and a resin film (B-stage film) having a thickness of 40 μm and having a residual solvent content of 1.0% by weight or more and 3.0% by weight or less on the PET film was obtained.

Thereafter, the laminated film was heated at 190° C. for 90 minutes to prepare a cured product of the resin film.

(Evaluation)

(1) Cutter Test

A laminated film cut out in a rectangular shape of 10 cm in length×5 cm in width was provided. On the B-stage film side of this laminated film, four slits of 8 cm in the longitudinal direction were made by a cutter. The cut surface was visually observed to examine presence or absence of chippings.

[Assessment Criteria in Cutter Test]

◯: No chippings

x: With chippings

(2) Folding Test

A B-stage film cut out in a rectangular shape of 10 cm in length×5 cm in width was provided. The B-stage film was folded by 90 degrees or 180 degrees, and then returned to a flat shape, and the condition of the resin was examined. The film is more easily cracked when folded by 180 degrees than when folded by 90 degrees.

[Assessment Criteria in Folding Test]

◯◯: The film is not cracked when folded either by 90 degrees or by 180 degrees.

◯: The film is cracked when folded by 180 degrees, and is not cracked when folded by 90 degrees.

x: The film is cracked when folded either by 90 degrees or by 180 degrees.

(3) Dielectric Loss Tangent

The resin film was cut to a size of 2 mm in width and 80 mm in length, and five such resin films were superposed on one another to obtain a laminated body having a thickness of 200 μm. For the obtained laminated body, the dielectric loss tangent was measured at a frequency of 1.0 GHz at room temperature (23° C.) by a cavity resonance method using “Cavity Resonance Perturbation Method Dielectric Constant Measuring Apparatus CP521” manufactured by Kanto Electronic Application and Development Inc. and “Network Analyzer N5224A PNA” manufactured by Keysight Technologies.

[Assessment Criteria for Dielectric Loss Tangent]

◯◯: The dielectric loss tangent is 0.0045 or less.

◯: The dielectric loss tangent is more than 0.0045 and not more than 0.005.

x: The dielectric loss tangent is more than 0.005.

(4) Average Linear Expansion Coefficient (CTE)

The cured product (using a resin film having a thickness of 40 μm) was cut into a size of 3 mm×25 mm. The average linear expansion coefficient (ppm/° C.) of the cut cured product over a temperature range from 25° C. to 150° C. under the condition of a tensile load of 33 mN and a temperature elevation rate of 5° C./rain using a thermomechanical analyzer (“EXSTAR TMA/SS6100” manufactured by SII NanoTechnology Inc.).

[Assessment Criteria for Average Linear Expansion Coefficient]

◯◯: The average linear expansion coefficient is 25 ppm/° C. or less.

◯: The average linear expansion coefficient is more than 25 ppm/° C. and 30 ppm/° C. or less.

x: The average linear expansion coefficient is more than 30 ppm/° C.

Compositions and results are shown in Tables 1 and 2 below.

TABLE 1

| | | | | Viscosity | | | | | | | |
|---|---|---|---|---|---|---|---|---|---|---|---|
| | | | | (mPa · s/ | Exam- | Exam- | Exam- | Exam- | Exam- | Exam- | Exam- |
| | | Trade name | Descriptions | 25° C.) | ple 1 | ple 2 | ple 3 | ple 4 | ple 5 | ple 6 | ple 7 |
| Ingredients | Solid epoxy | NC3000 | Biphenyl-type epoxy | Solid | 9 | 9.5 | | 8.5 | 8.5 | 8.5 | 8.5 |
| (parts by | compound | | resin | | | | | | | | |
| weight) | | XD1000 | Dicyclopentadiene- | Solid | | | 10.5 | | | | |
| | | | type epoxy resin | | | | | | | | |
| | Liquid epoxy | EP-4088S | Dicyclopentadiene | 230 | 0.6 | 0.15 | 0.95 | | | | |
| | compound | | dimethanol | | | | | | | | |
| | | | diglycidyl ether | | | | | | | | |
| | | GAN | Diglycidylaniline | 130 | | | | 0.7 | | | |
| | | EP-3980S | Diglycidylaniline | 30 | | | | | 0.6 | | |
| | | EX-216L | Cyclohexane | 55 | | | | | | 0.8 | |
| | | | dimethanol diglycidyl | | | | | | | | |
| | | | ether | | | | | | | | |
| | | EX-201-IM | Resorcinol diglycidyl | 400 | | | | | | | 0.7 |
| | | | ether | | | | | | | | |
| | | 840-S | Bisphenol A-type | 10000 | | | | | | | |
| | | | epoxy resin | | | | | | | | |
| | | 830-S | Bisphenol F-type | 4000 | | | | | | | |
| | | | epoxy resin | | | | | | | | |
| | Curing agent | EXB-9416- | Active ester resin- | | 17 | 17 | 17 | 17.5 | 17.5 | 17 | 17 |
| | | 70BK | containing liquid | | | | | | | | |
| | Curing | 2P4MZ | Imidazole compound | | 0.2 | 0.2 | 0.2 | 0.2 | 0.2 | 0.2 | 0.2 |
| | accelerator | | | | | | | | | | |
| | Thermoplastic | YX6954BH30 | Phenoxy resin- | | 3 | 3 | 3 | 3 | 3 | 3 | 3 |
| | resin | | containing liquid | | | | | | | | |
| | Inorganic | C4 Silica | | | 70 | 70 | 70 | 70 | 70 | 70 | 70 |
| | filler | | | | | | | | | | |

| Content (% by weight) of liquid epoxy compound having viscosity of 500 mPa · s or | | 6.3 | 1.6 | 8.3 | 7.6 | 6.6 | 8.6 | 7.6 |
|---|---|---|---|---|---|---|---|---|
| less at 25° C. based on 100% by weight of whole of epoxy compound | | | | | | | | |
| Evaluation | Cutter test | ◯ | ◯ | ◯ | ◯ | ◯ | ◯ | ◯ |
| | Folding test | ◯◯ | ◯ | ◯◯ | ◯◯ | ◯◯ | ◯◯ | ◯◯ |
| | Dielectric loss tangent | ◯ | ◯◯ | ◯ | ◯ | ◯ | ◯ | ◯ |
| | Average linear expansion coefficient (CTE) | ◯ | ◯◯ | ◯ | ◯ | ◯ | ◯ | ◯ |

TABLE 2

| | | | | Viscosity | Com- | Com- | Com- | |
|---|---|---|---|---|---|---|---|---|
| | | | | (mPa · s/ | parative | parative | parative | Comparative |
| | | Trade name | Descriptions | 25° C.) | Example 1 | Example 2 | Example 3 | Example 4 |
| Ingredients | Solid epoxy | NC3000 | Biphenyl-type epoxy resin | Solid | 10 | 7 | 9 | 9 |
| (parts by | compound | XD1000 | Dicyclopentadiene-type epoxy resin | Solid | | | | |
| weight) | Liquid epoxy | EP-4088S | Dicyclopentadiene dimethanol | 230 | 0.05 | 2 | | |
| | compound | | diglycidyl ether | | | | | |
| | | GAN | Diglycidylaniline | 130 | | | | |
| | | EP-3980S | Diglycidylaniline | 30 | | | | |
| | | EX-216L | Cyclohexane dimethanol | 55 | | | | |
| | | | diglycidyl ether | | | | | |
| | | EX-201-IM | Resorcinol diglycidyl ether | 400 | | | | |
| | | 840-S | Bisphenol A-type epoxy resin | 10000 | | | 0.6 | |
| | | 830-S | Bisphenol F-type epoxy resin | 4000 | | | | 0.6 |
| | Curing agent | EXB-9416-70BK | Active ester resin- | | 17 | 18 | 17 | 17 |
| | | | containing liquid | | | | | |
| | Curing | 2P4MZ | Imidazole compound | | 0.2 | 0.2 | 0.2 | 0.2 |
| | accelerator | | | | | | | |
| | Thermoplastic | YX6954BH30 | Phenoxy resin-containing liquid | | 3 | 3 | 3 | 3 |
| | resin | | | | | | | |
| | Inorganic | C4 Silica | | | 70 | 70 | 70 | 70 |
| | filler | | | | | | | |

| Content (% by weight) of liquid epoxy compound having viscosity of 500 mPa · s or | | 0.50 | 22.2 | 6.3 | 6.3 |
|---|---|---|---|---|---|
| less at 25° C. based on 100% by weight of whole of epoxy compound | | | | | |
| Evaluation | Cutter test | X | ◯ | X | X |
| | Folding test | X | ◯◯ | X | X |
| | Dielectric loss tangent | ◯◯ | X | ◯ | ◯ |
| | Average linear expansion coefficient (CTE) | ◯◯ | X | ◯ | ◯ |

### EXPLANATION OF SYMBOLS

11: Multilayer substrate
12: Circuit board
12a: Upper surface
13 to 16: Insulating layer
17: Metal layer

1. A resin composition comprising:
an epoxy compound;
a curing agent; and
an inorganic filler,
the epoxy compound containing a liquid epoxy compound having a viscosity of 500 mPa·s or less at 25° C., in an amount of 1% by weight or more and 10% by weight or less based on 100% by weight of the whole of the epoxy compound.

2. The resin composition according to claim 1, wherein the content of the inorganic filler is 60% by weight or more based on 100% by weight of components excluding a solvent in the resin composition.

3. The resin composition according to claim 1, wherein the inorganic filler contains silica.

4. The resin composition according to claim 1, wherein the curing agent contains an active ester compound.

5. The resin composition according to claim 1, wherein the liquid epoxy compound has a viscosity of 10 mPa·s or more at 25° C.

6. The resin composition according to claim 1, wherein the liquid epoxy compound has a cycloaliphatic structure, a glycidylamine structure having an aromatic ring structure, or a resorcinol structure.

7. The resin composition according claim 1, wherein the liquid epoxy compound is a liquid epoxy compound which does not contain a silicon atom.

8. The resin composition according to claim 1, comprising a thermoplastic resin.

9. A multilayer substrate comprising:
a circuit board; and
an insulating layer disposed on the circuit board,
the insulating layer being a cured product of the resin composition according to claim 1.
